(19) United States
(12) Patent Application Publication
(10) Pub. No.: US 2008/0036986 A1
(43) Pub. Date: Feb. 14, 2008

(54) PHOTOMASK, METHOD AND APPARATUS THAT USES THE SAME, PHOTOMASK PATTERN PRODUCTION METHOD, PATTERN FORMATION METHOD, AND SEMICONDUCTOR DEVICE

(75) Inventor: Hidenori Yamaguchi, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/612,897

(22) Filed: Dec. 19, 2006

(30) Foreign Application Priority Data
Aug. 11, 2006 (JP) 2006-219620

(51) Int. Cl. G03B 27/42; G03F 7/00

(52) U.S. Cl. 355/53; 430/5

(57) ABSTRACT

The photomask 10 comprises a substrate 11, a shot region 12 positioned on the substrate 11, mask patterns 13 formed within the shot region 12, and mask magnification information 14x formed in the outside exposure area (recto area) 14 of the shot region 12. The entire shot region 12 including the mask patterns 13 is elongated in the scanning direction (Y direction) indicated by the arrow. The mask magnifications of the mask pattern 13 are set to a magnitude of 4 in the X direction and a magnitude of 8 in the Y direction, for example. When the step-and-scan exposure technique is carried out using such a photomask in which the mask magnifications in the X and Y directions are different, a high-definition wafer having an equivalent longitudinal and transverse ratio can be transferred.

### TECHNICAL FIELD

The present invention relates to a photomask that can transfer a high-definition pattern onto a wafer, a method and apparatus for scanning exposure that uses the photomask, a method of producing a pattern for the photomask, a pattern formation method, and a semiconductor device.

### BACKGROUND OF THE INVENTION

A stepper is widely used as a reduced projection exposure apparatus for transferring a microcircuit pattern onto a resist or another photosensitive material formed on a wafer. The stepper is a step-and-repeat exposure apparatus that comprises an illumination optical system 41 having a beam source, a photomask 42, and a reduced projection optical system 43, as shown in FIG. 19A. In a stepper, a circuit pattern on a photomask 42 is reduced and projected onto the surface of a wafer 44, and the pattern is transferred onto the wafer 44 in a single process. When a one-shot exposure is completed, the stage on which the wafer 44 is mounted is stepped by a prescribed amount and the wafer is exposed again. This procedure is repeated until the entire wafer 44 has been exposed.

With more highly integrated semiconductor devices in recent years, there is an ever greater demand for micro-machining for wafers. Also, chip sizes have increased and projection lenses having a large diameter and high NA are needed for the steppers. In a stepper, however, the size of the exposable field (exposure field) covered in a single shot depends greatly on the diameter and aberration of the projection lens, and it has become difficult to assure a wider exposure field while maintaining high resolution because lens aberration increases as the diameter of the lens increases.

In view of the above, high-resolution step-and-scan exposure apparatus that have a wide exposure field have recently been used (Japanese Laid-open Patent Application No. JP09-167735). This exposure apparatus is referred to as a “scanner,” and is further provided with a photomask blind 46 for forming a slitted illumination area, and a single scan is carried out by synchronously scanning the photomask 42 and wafer 44 at a prescribed velocity in accordance with the reduced projection magnification of the reduced projection optical system 43, as shown in FIG. 19B. When a single scan exposure is completed, the stage on which the wafer is mounted is stepped by a prescribed amount and exposed again. The entire wafer is exposed by repeating this procedure. Since only the portion of the lens having low aberration is used in the scanner, the exposure field can be considerably increased in the lengthwise direction of the slits, and a large exposure field can be assured as a result. A pattern can therefore be transferred having greater detail than a stepper that simultaneously exposes the entire surface of the chips.

When a wafer is processed using a conventional stepper and scanner, a photomask on which a circuit pattern enlarged by a factor of 4 or 5 is formed is used in accordance with the reduction of the reduced projection optical system (projection lens). In a conventional photomask 50, the magnification (mask magnification) of the mask pattern 51 is set to be the same in the X and Y directions (a magnification of 4×4, for example), and a very small pattern is formed on the wafer by faithfully reproducing beam that has passed through the photomask 50 on the wafer, as shown in FIG. 20.

However, the pattern pitches are becoming increasingly narrow together with increasingly smaller semiconductor devices, and it is difficult to obtain the desired resolution. Also, the diffraction angle of the diffracted beam is increased as the size of the pattern on the photomask is reduced. There is therefore a problem in that it is difficult to confine beam in the projection lens, and the desired pattern cannot be obtained. Smaller patterns also create problems in that production yield of the photomask itself is reduced, resulting in delivery shortages.

It is therefore an object of the present invention to provide a photomask that can form a micro-pattern on a wafer and that also has good production yield.

Another object of the present invention is to provide a method of easily producing such a photomask.

Still another object of the present invention is to provide an improved exposure method and device for forming a very detailed pattern on the basis of a step-and-scan exposure technique in which such a photomask is used.

Yet another object of the present invention is to provide a pattern formation method that can form a very small pattern on a wafer.

An additional object of the present invention is to provide a highly integrated, high-performance semiconductor device.

### SUMMARY OF THE INVENTION

The above and other objects of the present invention can be accomplished by a photomask that is used in a scanning exposure apparatus, wherein a mask pattern is elongated in the scanning direction at a prescribed magnification bias.

With the photomask of the present invention, when a wafer is exposed using the scan-and-step method at a scanning velocity that corresponds to the mask magnification in the direction of the magnification bias, a higher definition pattern can be transferred in comparison with the case in which scan exposure is carried out using an ordinary photomask having the same mask magnification in the longitudinal and transverse directions, because the aspect dimensions have a magnification bias. Also, since the width of the space and the pattern in a single direction is elongated in comparison with an ordinary photomask, the processing precision of the pattern on the photomask can be made more flexible.

In the present invention, the lengthwise direction of the mask pattern is preferably more proximate to the direction orthogonal to the scanning direction than to the scanning direction, and the mask pattern preferably has a repeating pattern that is periodically arrayed with a prescribed pitch. The pattern resolution is particularly problematic when a line and space pattern or another repeating pattern is repeatedly formed at the pitch of the minimum processing dimensions, but when the width of the mask pattern on the photomask is elongated in the scanning direction as it is in the present invention, dramatic effects are achieved. The repeating pattern preferably includes any of the following: line and space, dense holes, a dense pillar pattern, a ring pattern, and a U-shaped pattern.

The photomask of the present invention preferably further comprises information about the magnification bias recorded in an outside exposure area. The magnification bias of the photomask can be read when the photomask is set in the exposure apparatus as long as the information about the magnification bias is recorded on the photomask, and the scanning velocity of the wafer can be automatically calculated based on the magnification bias, and the orientation of the wafer to be exposed can be adjusted to the desired orientation.

The photomask of the present invention may be an ordinary binary photomask, an OPC mask, or an attenuated, alternative, or chromeless phase shift mask, or a combination of these masks.

The above-described objects of the present invention can be obtained by an exposure method in which a wafer is exposed according to a step-and-scan technique that uses a photomask having a mask pattern elongated in the scanning direction at a prescribed magnification bias.

The present invention preferably comprises a photomask movement velocity determination step for determining the movement velocity of the photomask on the basis of the magnification bias and the movement velocity of the wafer, and a scan exposure step for exposing the photomask by moving the wafer at a prescribed scanning velocity while illuminating the wafer with slitted beam and moving the photomask at the movement velocity of the photomask in synchronism with the wafer. In accordance with this method, the scanning direction of the photomask is set in the elongation direction of the mask pattern by using a magnification-biased photomask that has a different mask magnification in the longitudinal and transverse directions, and a higher definition pattern can be transferred in comparison with a case in which scan exposure is carried out using an ordinary photomask. This result is obtained because the wafer is scanned and exposed while the photomask is moved at a prescribed velocity that is determined based on the mask magnification in the scanning direction. The photomask movement velocity determination step preferably includes a step for setting the photomask movement velocity to n times the movement velocity of the wafer, where n (n>1) is the mask magnification in the scanning direction, and m (n>m>1) is the mask magnification in the direction orthogonal to the scanning direction.

The present invention preferably further has a magnification bias information reading step for reading information about the magnification bias recorded on the photomask, prior to the scanning velocity determination step. When the photomask is set in the exposure apparatus, the scanning velocity of the wafer can be automatically calculated based on the mask magnification information by reading the mask magnification information of the photomask.

The present invention preferably further has a wafer 1 direction adjustment step for adjusting the orientation of the wafer on the basis of information about the magnification bias, prior to the scan exposure step. In the case of a photomask with magnification bias, the elongation direction of the mask pattern must be matched to the scanning direction, and the photomask handling is facilitated because the orientation of the photomask does not need to be adjusted when the orientation of the wafer is adjusted.

The above-described objects of the present invention can be achieved by an exposure apparatus for exposing a wafer in accordance with the step-and-scan technique by using a photomask that has a mask pattern elongated in the scanning direction at a prescribed magnification bias, the exposure apparatus comprising an illumination system for illuminating slitted beam on the photomask, a reduced projection exposure apparatus for reducing and projecting on the wafer the beam that has passed through the photomask, and scan exposure means for scanning and exposing the wafer at a prescribed scanning velocity in accordance with one of the mask magnifications of the photomask.

In the present invention, the scan exposure means preferably comprises a photomask stage on which a photomask is mounted, a wafer stage on which the wafer is mounted, and scan control means for moving the photomask stage and the wafer stage in the reverse direction in synchronism with each other. In this case, the scan exposure means preferably sets the movement velocity of the photomask stage to the movement velocity of the wafer stage, where n (n>1) is the mask magnification in the scanning direction, and m (n>m>1) is the mask magnification in the direction orthogonal to the scanning direction.

According to the exposure apparatus of the present invention, a higher definition pattern can be transferred in comparison with the case in which scan exposure is carried out using an ordinary photomask in which the mask magnification longitudinal and transverse directions are equal. This result is obtained because scanning is carried out using the step-and-scan technique at a scanning velocity that is m times greater in the magnification bias direction, using a photomask with biased aspectual dimensions.

The exposure apparatus of the present invention preferably further comprises magnification bias information reading means for reading information about the magnification bias recorded on the photomask, and scanning velocity determination means for determining the movement velocity of the photomask stage on the basis of information about the magnification bias and the movement velocity of the wafer. When the photomask is set in the exposure apparatus, the movement velocity of the photomask can be automatically calculated by reading the information about the magnification bias of the photomask, and the labor required to manually input the information about the magnification bias can be saved.

In the exposure apparatus of the present invention, the wafer stage preferably further comprises wafer rotation means, and the wafer rotation means adjusts the orientation of the wafer on the basis of information about the magnification bias. In the case of a photomask having a magnification bias, the elongation direction of the pattern must be matched to the scanning direction, but the photomask handling is facilitated because the orientation of the photomask does not need to be adjusted when the orientation of the wafer is adjusted.

The exposure apparatus of the present invention may be an immersion exposure method, a modified illumination method, or a combination of the two.

The above-described objects of the present invention can also be achieved by a photomask pattern production method comprising an actual pattern production support step for supporting production of a drawing of an actual pattern having an equivalent longitudinal and transverse ratio projected on a wafer, an auxiliary pattern generation step for generating an auxiliary pattern on the basis of the actual pattern, a combined pattern generation step for generating a combined pattern of the actual pattern and the auxiliary pattern, and a conversion step for converting the dimensions in the longitudinal and transverse directions of the combined pattern using a prescribed mask magnification. In this case, the actual pattern production support step preferably includes a step for displaying the actual pattern and the dimension display scale thereof using an equivalent longitudinal and transverse ratio, and the conversion step preferably includes a step for displaying the combined pattern using an equivalent longitudinal and transverse ratio and displaying the dimensions after the dimension display scale thereof has been enlarged. According to this method, a pattern that is similar to the actual pattern can be handled on a pattern production screen without consideration for the shape of the biased pattern.

The above-described objects of the present invention can also be achieved by a pattern formation method that uses the photomask of the present invention, the pattern formation method comprising a step for forming a first wiring pattern on a wafer, and a step for rotating the wafer while the photomask scanning direction is kept the same direction, and forming a second wiring pattern that is substantially orthogonal to the first wiring pattern on the wafer.

The above-described objects of the present invention can also be achieved by a pattern formation method that comprises an ordinary pattern formation step for forming a pattern using a photomask in which the mask magnification is equal in the longitudinal and transverse directions, and a high-resolution pattern formation step for forming a pattern using a photomask in which the mask magnifications are different in the longitudinal and transverse directions.

The above-described objects of the present invention can also be achieved by a pattern formation method in which scanning and exposing is carried out in the direction orthogonal to the lengthwise direction of a repeating pattern when a hole pattern is formed in accordance with the repeating pattern on a wafer that has the pattern.

The above-described objects of the present invention can also be achieved by a semiconductor device manufactured using the photomask according to the present invention. A high density, high performance semiconductor device can thereby be obtained.

The above-described objects of the present invention can also be achieved by a semiconductor device manufactured using the exposure method according to the present invention. A high density, high performance semiconductor device can thereby be obtained.

The above-described objects of the present invention can also be achieved by a semiconductor device manufactured using the pattern formation method according to the present invention. A high density, high performance semiconductor device can thereby be obtained.

According to the present invention, a photomask can be provided that can form a micro-pattern on a wafer and has good production yield.

According to the present invention, a photomask production method can be provided that can form a micro-pattern on a wafer and has good production yield.

According to the present invention, an exposure method and device can be provided that can form a high-definition pattern according to the step-and-scan technique using a photomask in which the mask magnifications in the X and Y directions are different.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic plan view showing the configuration of the photomask according to the preferred embodiments of the present invention;

FIG. 2 is a local sectional view of the photomask;

FIG. 3 is a schematic plan view showing the OPC mask pattern;

FIG. 4A is a schematic cross-sectional view showing the half tone type phase shift mask pattern;

FIG. 4B is a schematic cross-sectional view showing the Levenson-type phase shift mask pattern;

FIG. 5A is a schematic plan view showing the mask patterns 13 (a repeating pattern of lines and spaces) on a biased-magnification photomask 10 contrasted with an actual pattern that is reduced and projected onto a wafer;

FIG. 5B is a schematic plan view showing the mask patterns 13 (a hole pattern) on a biased-magnification photomask 10 contrasted with an actual pattern that is reduced and projected onto a wafer;

FIG. 6A is a schematic view that describes the effects of a biased-magnification photomask, and especially showing a pattern shape on a wafer formed using an ordinary photomask;

FIG. 6B is a schematic view that describes the effects of a biased-magnification photomask, and especially showing a pattern shape on a wafer formed using the biased-magnification photomask of the present embodiment;

FIG. 7A is a schematic view that describes the effects of a biased-magnification photomask, and especially showing an intensity distribution of light that has passed through an ordinary photomask;

FIG. 7B is a schematic view that describes the effects of a biased-magnification photomask, and especially showing the intensity distribution of light that has passed through a biased-magnification photomask;

FIG. 8A is a view showing the rectangular shaped (pillar) pattern of the effects of a biased-magnification photomask;

FIG. 8B is a view showing the substantially ring-shaped pattern of the effects of a biased-magnification photomask;

FIG. 8C is a view showing the U-shaped pattern of the effects of a biased-magnification photomask;

FIG. 9 is a schematic view showing the relationship between the direction of the mask pattern and the scan direction;

FIG. 10 is a flowchart showing the production sequence of a biased-magnification photomask;

FIG. 11A is a schematic view showing a photomask drawing screen (the magnification prior to conversion);

FIG. 11B is a schematic view showing a photomask drawing screen (the magnification after conversion);

FIG. 12 is a schematic perspective view showing the configuration of a scanner 20 in which the biased-magnification photomask 10 can be used;

FIG. 13 is a flowchart that shows the sequence for scanning and exposing the wafer using the scanner 20;

FIG. 14 is a schematic diagram showing a configuration of the exposure apparatus according to another embodiment of the present invention;

FIG. 15 is a schematic diagram showing a configuration of the exposure apparatus according to yet another embodiment of the present invention;

FIG. 16 is a schematic diagram that describes the principle of the off-axis illumination system;

FIGS. 17A through 17F are schematic plan views for explaining the double exposure method;

FIGS. 18A and 18B are schematic cross-sectional views showing a method of controlling the width of the mask pattern formed on the photomask;

FIG. 19A is a schematic diagram showing a prior step and repeat type projection exposure system (stepper);

FIG. 19B is a schematic diagram showing a prior step and scan type projection exposure system (scanner); and

FIG. 20 is a plan view showing a structure of the prior photomask.

### DETAILED DESCRIPTION OF THE EMBODIMENTS

Preferred embodiments of the present invention will now be described in detail hereinafter with reference to the accompanying drawings.

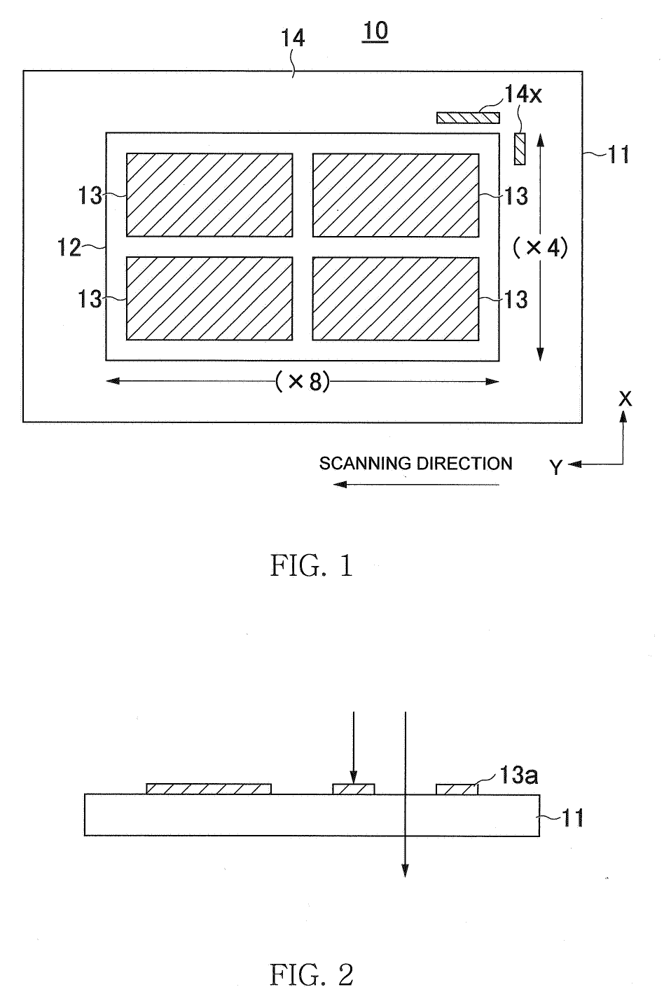

FIG. 1 is a schematic plan view showing the configuration of the photomask according to the preferred embodiments of the present invention. FIG. 2 is a local sectional view of the photomask.

As shown in FIG. 1, the photomask 10 comprises a substrate 11, a shot region 12 positioned on the substrate 11, mask patterns 13 formed within the shot region 12, and mask magnification information 14x formed in the outside exposure area 14 of the shot region 12. In the photomask 10 of the present invention, four chip patterns are disposed within the shot region 12, and four chips can be exposed in a single shot, as shown in the diagram.

The substrate 11 is also referred to as a mask blank and is composed of a transparent quartz substrate or a glass substrate. As shown in FIG. 2, the surface of the quartz substrate is partially covered with chromium (Cr) or another light-blocking film 13a, and mask patterns 13 are formed thereby. The mask patterns 13 may be negative or positive patterns.

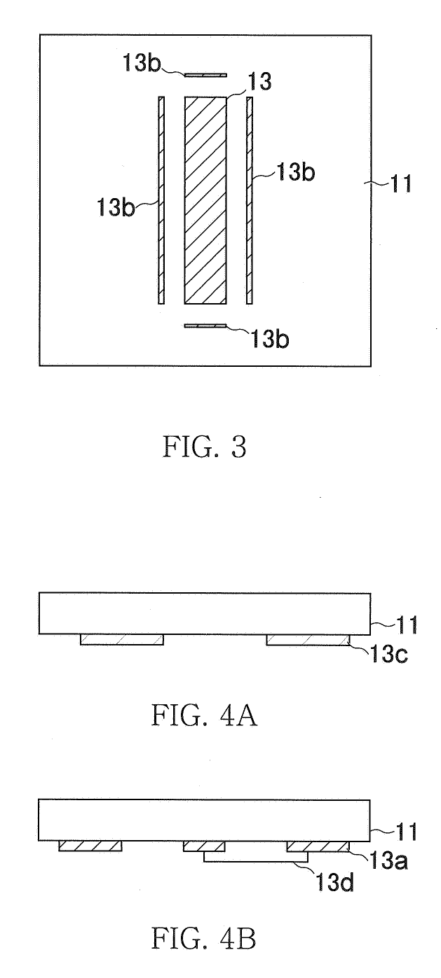

The photomask 10 of the present embodiment may be an ordinary binary photomask shown in FIGS. 1 and 2, and may be an OPC (Optical Proximity effect Correction) mask on which an OPC auxiliary pattern 13b is formed on the periphery of the mask pattern 13 shown in FIG. 3. The photomask may also be a half-tone (also referred to as “attenuated”) phase shift mask that uses a half light-blocking film 13c such as that shown in FIG. 4a, or may be a Levinson (also referred to as “alternative”) phase shift mask that uses a thin film (phase shifter) 13d or the like such as that shown in FIG. 4B. The photomask may also be a chromeless phase shift mask in which no light-blocking films composed of chromium (Cr) are used at all. A combination of the above may also be used.

In the present embodiment, the entire shot region 12 including the mask patterns 13 is elongated in the scanning direction (Y direction) indicated by the arrow, and the mask magnifications in the X and Y directions of the mask pattern 13 formed in the shot region 12 are also different, as shown in FIG. 1. The mask magnifications of the mask pattern 13 in the diagram are set to a magnitude of 4 in the X direction and a magnitude of 8 in the Y direction, for example. In the present embodiment, when the step-and-scan exposure technique is carried out using such a photomask (hereinafter referred to as “biased-magnification photomask”) in which the mask magnifications in the X and Y directions are different, a high-definition wafer having an equivalent longitudinal and transverse ratio can be transferred by using the Y direction as the scanning direction and moving the photomask in the Y direction at a velocity that is 8 times greater than the scanning velocity of the wafer.

The recto area 14 is used as the formation area for a positioning mask, and is also used as a recording area for the mask magnification information 14x. In particular, in the present embodiment, the mask magnification information 14x itself is used as a positioning mask. The mask magnification information 14x is information that indicates the mask magnifications of the photomask in the X and Y directions and is recorded in a format that uses numbers, codes, or barcodes, for example. The mask magnifications of the photomask are ordinarily the same in the X and Y directions, but the mask magnifications in the X and Y directions are different in a biased-magnification photomask. A scanner reads the mask magnification information 14x, and the scanning velocity can be determined by calculating the magnification bias from the mask magnification information 14x. The mask magnification may be set in the Y direction alone because the mask magnification in the X direction is set to a unique value on the basis of the lens magnification of the exposure apparatus in which the photomask is used. The mask magnification may be set to be the magnification bias of the Y direction (scanning direction) with respect to the X direction (direction orthogonal to the scanning direction) and recorded in the recto area 14. In this case, the magnification bias of the photomask 10 is “2.” The mask magnifications of the X and Y directions can be handled as information about the magnification bias of the photomask 10.

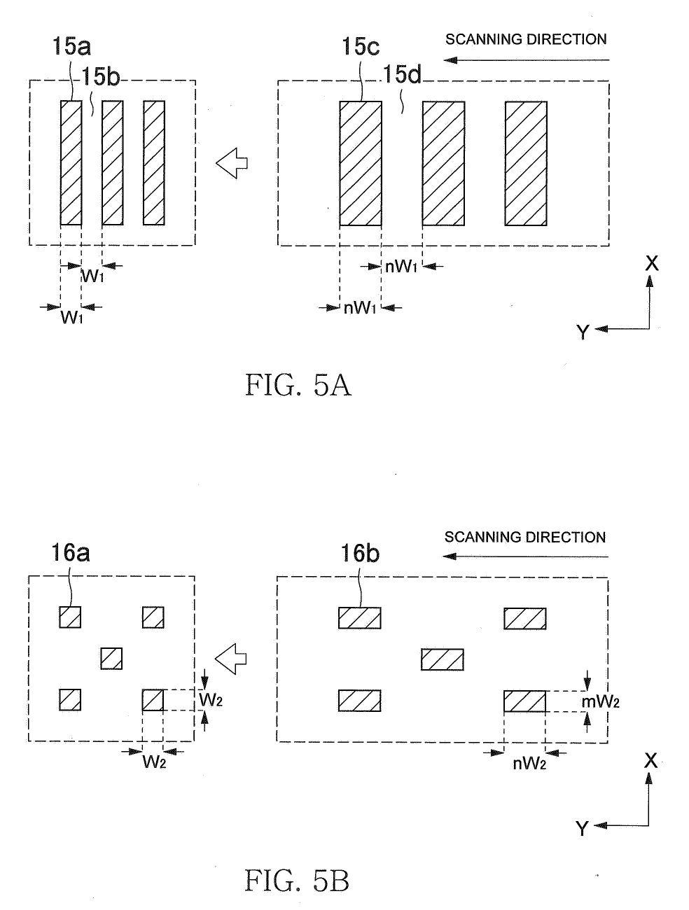

FIGS. 5A and 5B are schematic plan views showing the mask patterns 13 on a biased-magnification photomask 10 contrasted with an actual pattern that is reduced and projected onto a wafer. FIG. 5A shows a repeating pattern of lines and spaces, and FIG. 5B shows a hole pattern.

As shown in FIG. 5A, when a repeating pattern of lines 15a and spaces 15b having a width W₁ is to be formed as an actual pattern on a wafer, the widths of the lines 15a and spaces 15b on the photomask are both set to nW₁. In this case, “n” is the mask magnification in the Y direction. The mask magnification n in the Y direction is set to a magnification that exceeds the mask magnification m of the X direction, and the mask magnification m in the X direction is set to be equal to the reduction of the reduced projection optical system (projection lens), i.e., n>m>1. Therefore, when, for example, the reduction of the reduced projection optical system is a magnitude of 4, and the magnification bias is n/m=2 in the X and Y directions, the mask magnification in the Y direction is set to n=8, and the lines 15c and spaces 15d are set to “8W₁” on the biased-magnification photomask. The scanning direction of the mask pattern is set to the elongation direction of the lines and spaces, as indicated by the arrow, i.e., the direction that is substantially orthogonal to the width direction of the lines and spaces.

As shown in FIG. 5B, when a hole pattern 16a that has a length and width of W₂ is to be formed as an actual pattern on a wafer, the length of the hole pattern 16b on the photomask is set to mW₂, and the width is set to nW₂. In this case, “m” is the mask magnification in the X direction, and “n” is the mask magnification in the Y direction. The mask magnification n in the Y direction is set to a magnification that exceeds the mask magnification m of the X direction, and the mask magnification m in the X direction is set to be equal to the reduction of the reduced projection optical system (projection lens), i.e., n>m>1. Therefore, when the reduction of the reduced projection optical system is equal to 4, the mask magnification in the X direction is set to m=4. When the magnification bias is set to n/m=2 in the X and Y directions, the mask magnification in the Y direction is set to n=8, the length of the hole pattern 16b on the biased-magnification photomask is set to “4W₂”, and the width is set to “8W₂.” The scanning direction of the mask pattern is set to the width direction of the hole pattern, i.e., the direction that is substantially orthogonal to the lengthwise direction of the hole pattern, as indicated by the arrow. However, when the length and width of the hole pattern is W₂, either of the directions may be set to be the width direction.

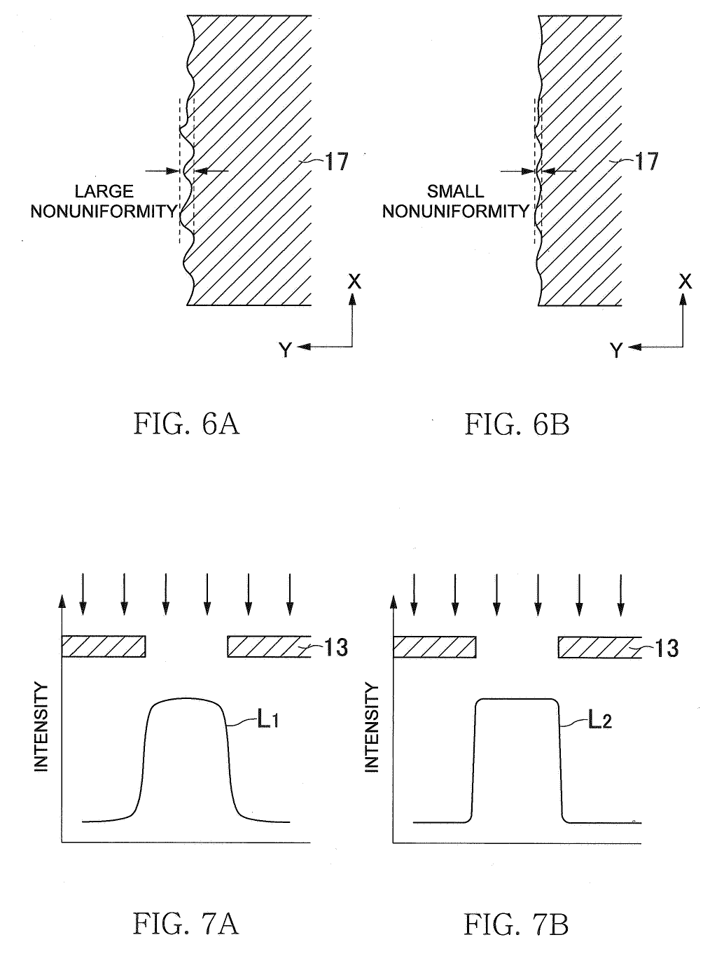

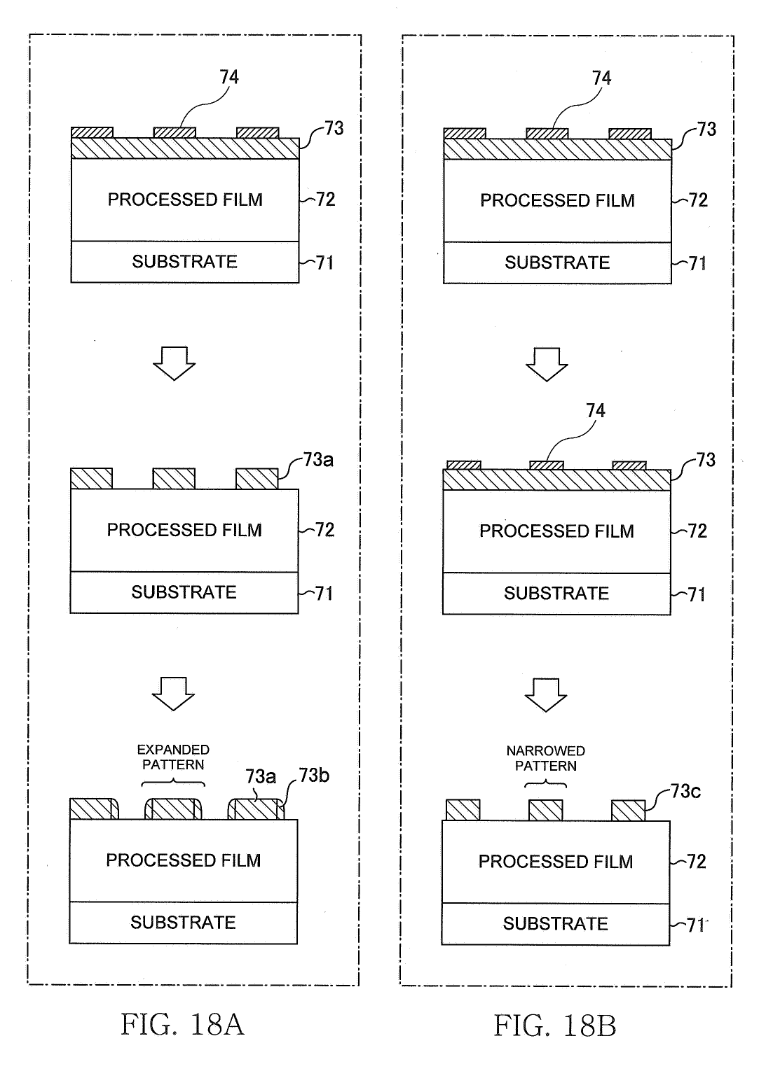

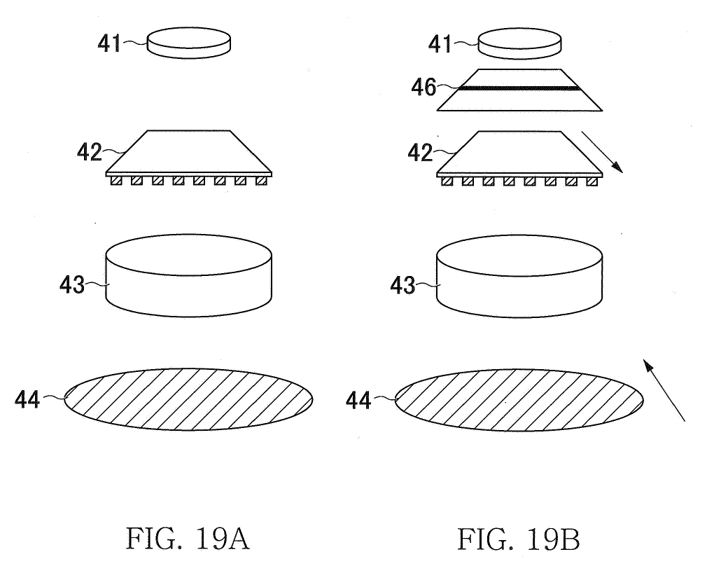

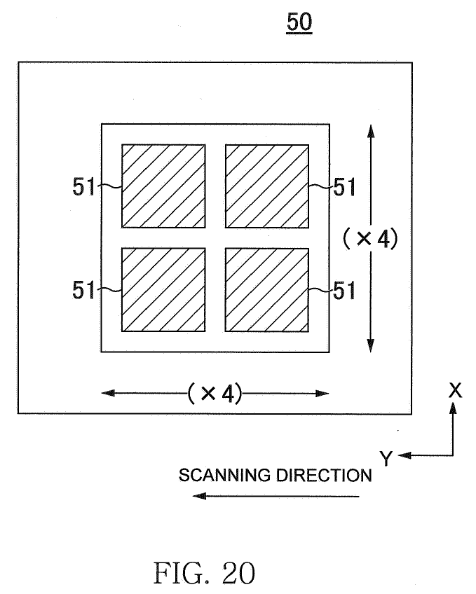

FIGS. 6 and 7 are schematic views that describe the effects of a biased-magnification photomask. FIG. 6A shows a pattern shape on a wafer formed using an ordinary photomask (see FIG. 18) in which the mask magnifications in the X and Y directions are equal. FIG. 6B shows a pattern shape on a wafer formed using the biased-magnification photomask of the present embodiment. FIG. 7A shows an intensity distribution of light that has passed through an ordinary photomask, and FIG. 7B shows the intensity distribution of light that has passed through a biased-magnification photomask.

As shown in FIG. 6A, when a mask pattern is transferred onto a photomask using an ordinary exposure method and an ordinary photomask in which the mask magnification is (m×m), nonuniformity at the edges along the X direction of the actual pattern 17 increases. In contrast, when a biased-magnification photomask having a mask magnification of (m×n) is moved at a velocity of n times the scanning velocity and a mask pattern is transferred, nonuniformity at the edges of the actual pattern 17 can be reduced in comparison with an ordinary photomask, and a high-definition pattern can be formed, as shown in FIG. 6B.

As shown in FIG. 7A, when a pattern is transferred onto a photomask using an ordinary exposure method and an ordinary photomask in which the mask magnification is (m×m), the rising and failing portions of the intensity pattern L₁ of the light that has passed through the mask patterns 13 are somewhat gently sloped. In contrast, when a biased-magnification photomask having a mask magnification of (m×n) is moved at a velocity of n times the scanning velocity of the wafer to transfer a mask pattern, a high-definition pattern can be formed because the rising and falling portions of the intensity pattern L₂ of the light that has passed through the mask patterns 13 drop sharply away, as shown in FIG. 7B. This phenomenon becomes particularly more dramatic as the dimensions of the mask pattern become proximate to the wavelength of the light.

Therefore, when a repeating pattern of lines and spaces such as word lines and data lines is formed with a narrow pitch, nonuniformity at the edges of a line pattern can be reduced by setting the direction orthogonal to the elongated direction of the patterns as the scan direction and setting the width of the lines and spaces to be greater than the width determined by the reduced projection magnification. In other words, by forming a micro wiring pattern in this manner, nonuniformity at the edges of the pattern that intersect with the scan direction can be reduced and a higher-definition pattern can be formed while ensuring the same conventional processing precision in relation to the scan direction and a parallel pattern.

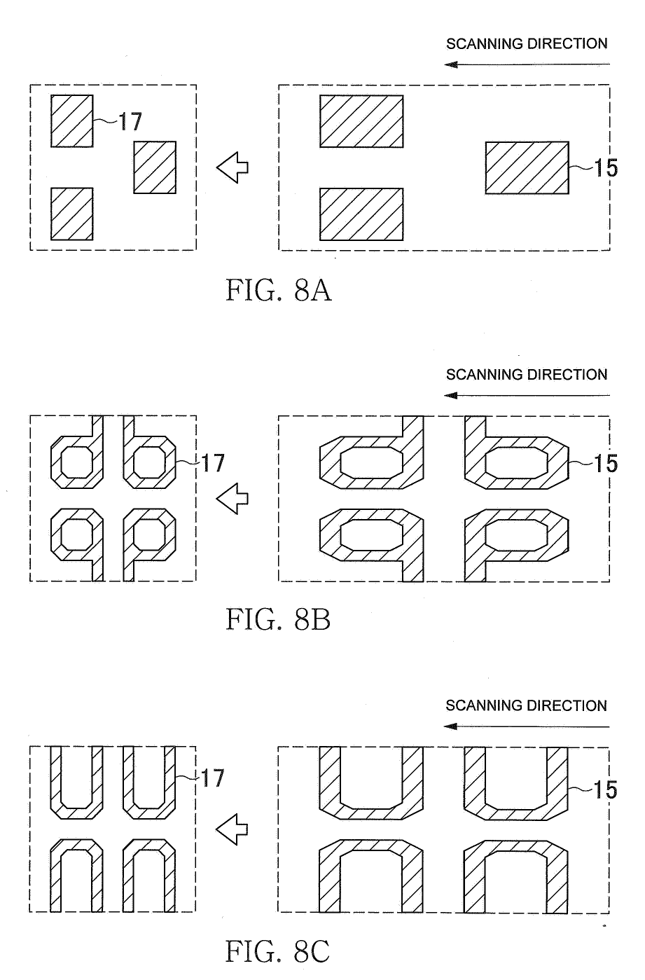

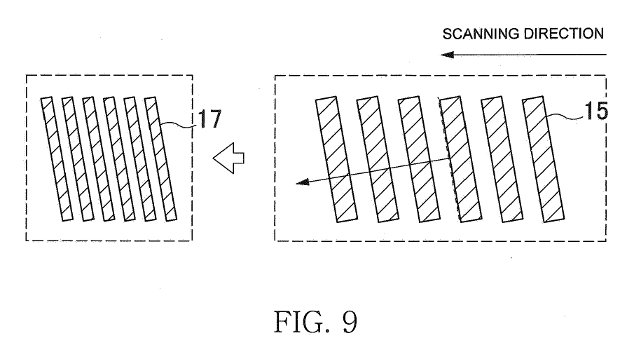

The mask pattern of the biased-magnification photomask is not limited to holes or the lines and shapes described above, and various shapes may be considered. The pattern may be the rectangular shape (pillar) shown in FIG. 8A, the substantially ring-shaped pattern shown in FIG. 8B, or the U-shaped pattern shown in FIG. 8C. Also, the lengthwise direction of the mask pattern is not necessarily required to be oriented in the direction orthogonal to the scan direction, and the lengthwise direction is preferably more proximate to the direction (X direction) orthogonal to the scan direction than to the scan direction (Y direction), as shown in FIG. 9. The resolution of the pattern formed on the wafer can be sufficiently increased with such an orientation, though not to the extent of the case in which the orientation is orthogonal.

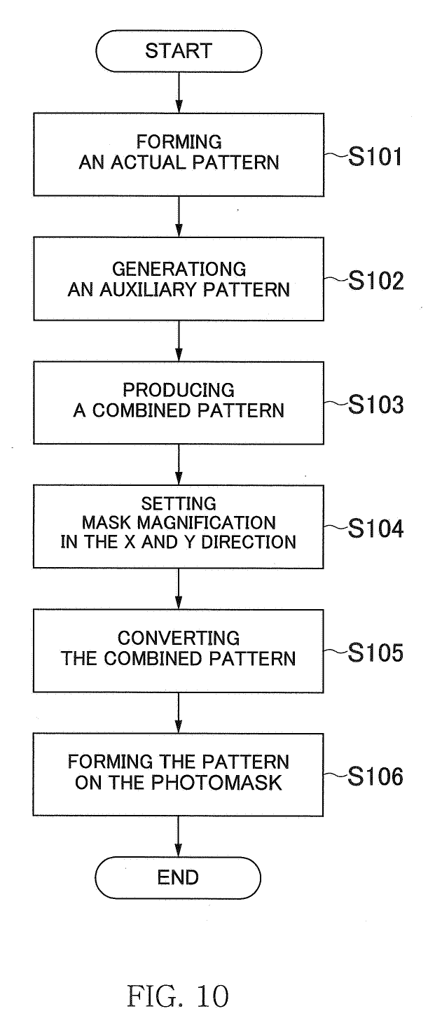

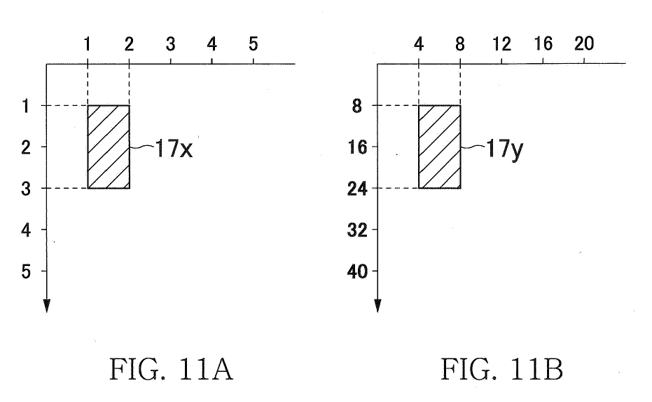

FIG. 10 is a flowchart showing the production sequence of a biased-magnification photomask. FIGS. 1A and 11B are schematic views showing a photomask drawing screen. FIG. 11A shows the magnification prior to conversion, and FIG. 11B shows the magnification after conversion.

As shown in FIG. 10, first step in the production of a biased-magnification photomask is to design an actual pattern, which is the pattern that is actually formed on the wafer (S101). Pattern-design CAD is used to produce a drawing of an actual pattern, and the drawing of a master pattern is supported by use of CAD. In this case, the initial grid for producing an actual pattern is set to the same scale in both the X and Y directions of the actual pattern 17x.

An auxiliary pattern is subsequently generated based on the actual pattern (S102). Examples of an auxiliary pattern include an OPC pattern for forming an OPC mask, a shift pattern for forming a phase shift mask and the like. A combined pattern consisting of actual data and auxiliary data is produced thereafter (S103).

Next, the mask magnifications in the X and Y directions of the combined pattern are set (S104). When an ordinary photomask is to be produced, the mask magnifications in the X and Y directions are set to be the same (i.e., m×m), as described above. However, when a biased-magnification photomask is to be produced, the mask magnification of the X direction or the Y direction is set to be greater than the mask magnification of the remaining direction. Setting the X direction or the Y direction to a higher magnification can be determined in accordance with the shape of the master pattern. When a large number of repeating patterns of lines and spaces are present in the combined pattern, the direction that is substantially orthogonal to the elongation direction of the patterns is preferably set to be the higher magnification. Nonuniformity at the edges of the line pattern can thereby be reduced, and a high-definition pattern can be formed on a wafer. The desired dimensional corrections are preferably set after the mask magnification has been set (S104) when the photomask drawing machine for producing a photomask must be set up or the dimensional corrections (dimensional bias) for use during photomask production must be set.

Next, the dimensions in the X and Y direction of the combined pattern are converted based on the mask magnifications in the X and Y direction thus set (S105). Even with a biased pattern, the pattern 17y having the same mask magnification in the longitudinal and transverse directions is displayed on the screen, and only the scale for displaying the dimensions is converted and displayed, as shown in FIG. 11B. Therefore, the pattern designer can handle an actual pattern on the screen as an analogous pattern without consideration for the shape of the biased-magnification pattern. The biased-magnification photomask of the present embodiment is completed by actually forming the combined pattern produced in this manner on a photomask (S106).

Next, the method of exposing a wafer in which a biased-magnification photomask is used will be described.

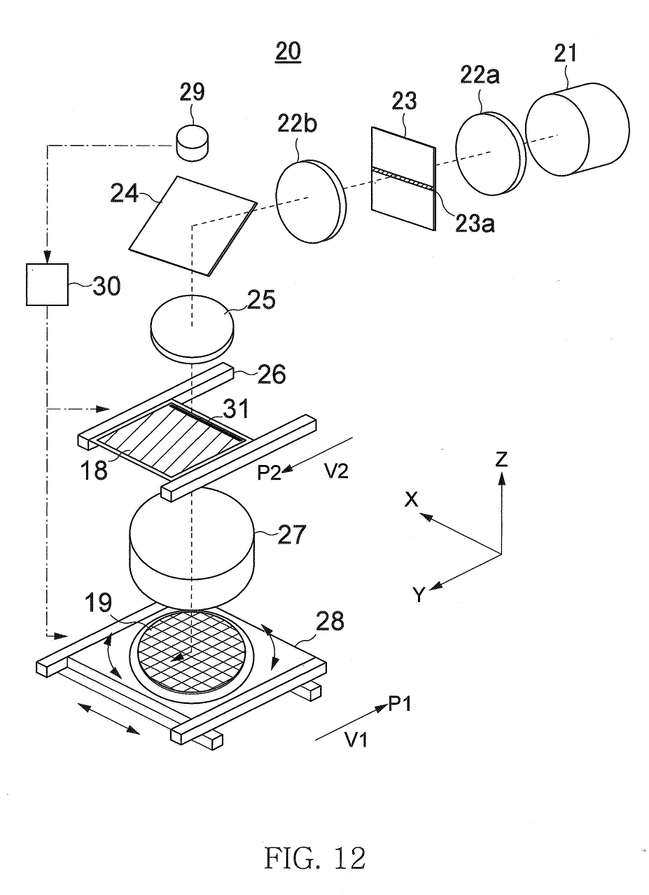

FIG. 12 is a schematic perspective view showing the configuration of a scanner 20 in which the biased-magnification photomask 10 can be used.

As shown in FIG. 12, the scanner 20 comprises a light source 21, lenses 22a and 22b, a photomask blind 23 disposed between the lenses 22a and 22b, a mirror 24 for changing the travel direction of light that has passed through the lens 22b, a condenser lens 25, and a projection lens 27. The illumination system of the scanner 20 is composed of the light source 21, lenses 22a and 22b, photomask blind 23, mirror 24, and condenser lens 25. The reduced projection optical system of the scanner 20 consists of the projection lens 27. The scanner 20 further comprises a photomask stage 26 on which a photomask 18 having a drawn mask pattern is mounted, a wafer stage 28 mounted with a wafer 19 to which a resist or another photosensitive material has been applied, an imaging device 29 that can image the surface of a photomask, and a controller 30 for controlling the components.

Light sources that may be used for the light source 21 include g-, h-, or i-line lasers; a KrF excimer laser, an ArF excimer laser, an F₂ excimer laser, EUV, and X rays or other energy rays. The photomask 18 can be moved in the Y direction by using the photomask stage 26, and the movement velocity V₂ and the position in the Y direction are controlled by the controller 30. The wafer 19 can be moved in the X and Y directions by using the wafer stage 28, and the movement velocity V₁ in the Y direction and the position in the X and Y directions are controlled by the controller 30. The wafer stage 28 has a wafer rotation mechanism, and the orientation of the wafer 19 can be rotated 360°. The photomask stage 26 and wafer stage 28 are synchronized and controlled by the controller 30. The entire mask pattern on the photomask is reduced and projected while the wafer 19 and photomask 18 are mutually synchronized and moved in the reverse direction.

The photomask blind 23 is irradiated with light emitted from the light source 21 by way of the lens 22a. The photomask blind 23 has a slit 23a that extends in the X direction as shown in the diagram to thereby obtain a slitted illumination area 31. The light that is limited by the photomask blind 23 is directed to the photomask 18 by way of the lens 22b, mirror 24, and condenser lens 25. Light that has passed through the photomask 18 is transmitted by the projection lens 27 and directed to the wafer 19.

In this manner, the slitted illumination area is moved in the scan direction at a scanning velocity of V₁ to scan and expose an entire prescribed exposure area on the wafer by moving the wafer 19 at a prescribed velocity V₁ in the opposite direction to the scan direction, indicated by the arrow P1, while the wafer 19 is irradiated by slitted light that has passed through the photomask 18. On the other hand, the slitted illumination area scans the entire mask pattern on the photomask 18, and the entire mask pattern is reduced and projected in a prescribed exposure area on the wafer 19 by moving the photomask 18 at a prescribed velocity V₂ in the opposite direction of the movement direction of the wafer 19 (i.e., the scan direction), as indicated by the arrow P2.

In this case, with an ordinary photomask having a mask magnification of m×m (m>1), which has been set based on the reduced projection magnification m of the projection lens 27, a desired pattern that corresponds to the mask magnification can be formed by setting the movement velocity V₂ of the photomask to m times that of the movement velocity V₁ of the wafer, i.e., V₂=m×V₁. In contrast, with a biased-magnification photomask having a mask magnification of m×n (n>m>1), a pattern having an equivalent longitudinal and transverse ratio can be formed on a wafer in the same manner as an ordinary photomask by setting the movement velocity V₂ of the photomask to n times that of the movement velocity V₁ of the wafer, i.e., V₂=n×V₁. Also, a high-definition pattern can be formed without nonuniformity at the edges of the pattern along the X direction in comparison with an ordinary photomask.

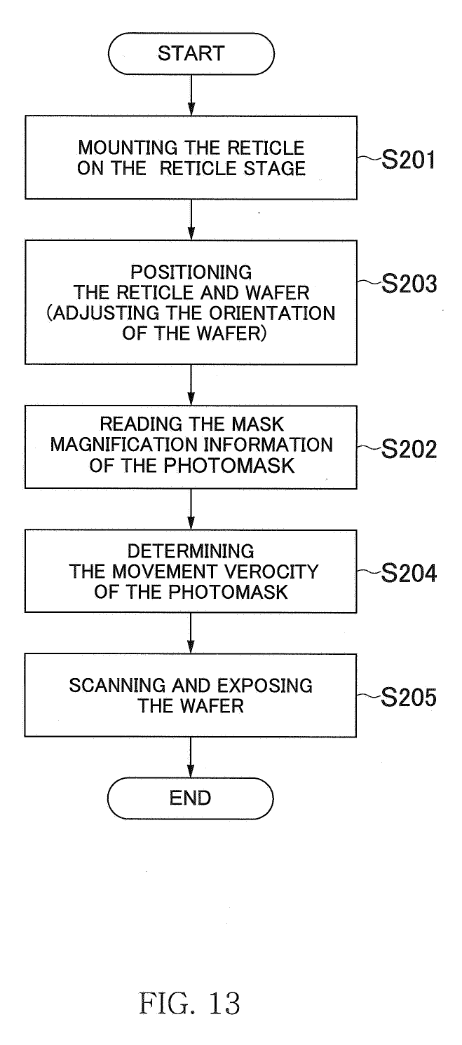

Next, the sequence for scanning and exposing the above-described wafer using the scanner 20 is described with reference to FIG. 13.

When the wafer 19 is scanned and exposed using the scanner 20 described above, the photomask 18 is first mounted on the photomask stage 26 (S201). In the particular case that a biased-magnification photomask is mounted, the elongation direction of the pattern is set so as to be oriented in the scan direction. The recto area on the photomask 18 is subsequently read by the imaging device 29, the photomask 18 and wafer 19 are positioned relative to each other on the basis of the recto area, and the mask magnification information of the photomask 18 is read (S202).

Positioning the photomask 18 and wafer 19 also involves adjusting the orientation of the wafer 19 with respect to the scan direction (S203). In the case of an ordinary photomask, the orientation of the mask pattern can be freely determined in accordance with the orientation of the wafer without restriction in the orientation of the mask pattern on the photomask 18 because the mask pattern has an equal longitudinal and transverse ratio. In the case of a biased-magnification photomask in which the mask magnification is different in the X and Y directions, the elongation direction of the pattern must be matched to the scan direction. Therefore, the orientation of the mask pattern is limited by the scan direction, and the orientation of the photomask 18 mounted on the scanner 20 is determined as a matter of course. For this reason, the orientation of the photomask 19 is matched to the orientation of the photomask 18 by rotating the wafer stage 28 a prescribed amount as required.

Next, the movement velocity V₂ of the photomask 18 is determined based on the mask magnification information (S204) The movement velocity of the photomask is determined based on the mask magnification of the scan direction (Y direction) and the movement velocity V₁ of the wafer 19. With an ordinary photomask having a mask magnification of m×m (m>1), for example, which has been set based on the reduced projection magnification m of the projection lens 27, the movement velocity V₂ of the photomask is set to m times that of the movement velocity V₁ of the wafer, i.e., V₂=m×V₁. It is therefore possible to form a desired pattern corresponding to the mask magnification.

In contrast, with a biased-magnification photomask having a mask magnification of m×n (n>m>1), the movement velocity V₂ of the photomask is set to n times that of the movement velocity V₁ of the wafer, i.e., V₂=n×V₁. In the case of a biased-magnification photomask having a mask magnification of 4×8, for example, the movement velocity of the photomask is set to 8 times that of the scanning velocity. Also, in the case of a biased-magnification photomask having a mask magnification of 4×16, for example, the movement velocity of the photomask is set to 16 times that of the scanning velocity. A pattern having an equivalent longitudinal and transverse ratio can thereby be formed on the wafer 19, in the same manner an ordinary photomask. Also, a high-definition pattern can be formed without nonuniformity at the edges of the pattern along the X direction in comparison with an ordinary photomask.

Next, the wafer 19 is scanned and exposed (S205). In scan exposure, the slitted illumination area on the wafer 19 is moved in the Y direction at a prescribed scanning velocity by moving the photomask stage 26 and wafer stage 28 in mutually opposite directions while illuminating the photomask 18 with slitted luminous flux. In this manner, the entire pattern on the photomask 18 is transferred onto the wafer 19 by scanning the entire photomask 18. In this case, an ordinary photomask is scanned and exposed in an ordinary manner in which the photomask 18 is moved at a velocity of m×V₁ in the Y direction, and a biased-magnification photomask is scanned at a velocity of n×V₁ in the Y direction. Thus, when the photomask is scanned at a prescribed velocity in accordance with the mask magnification of the photomask, a high-definition pattern having an equivalent longitudinal and transverse ratio can be formed on the wafer.

As described above, according to the present embodiment, the photomask is moved at a velocity of n times that of the scanning velocity of the wafer, with the Y direction used as the scan direction, using a biased-magnification photomask in which the mask magnification in the X direction is m (m>1) and the mask magnification in the Y direction is n (n>m>1). Therefore, a pattern having an equivalent longitudinal and transverse ratio can be formed on the wafer, and a pattern having a higher definition than an ordinary photomask can be formed.

The biased-magnification photomask of the present invention can furthermore be applied to a variety of scan and exposure systems.

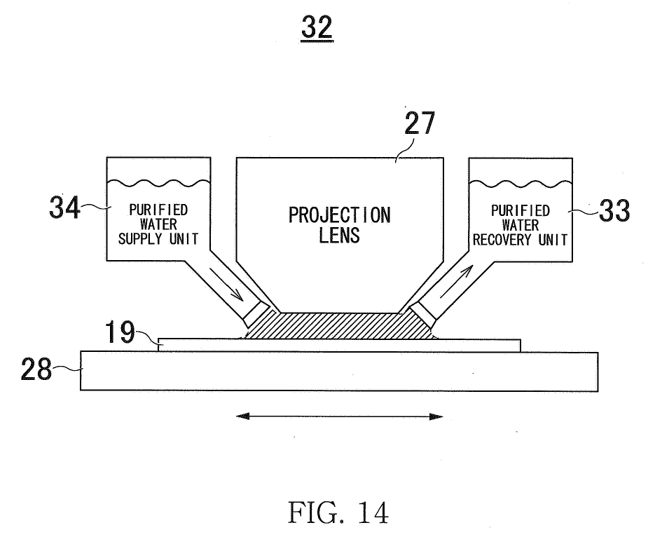

FIG. 14 is a schematic diagram showing a configuration of the exposure apparatus according to another embodiment of the present invention.

The immersion exposure method is adopted in the exposure apparatus 32, and the exposure apparatus 32 comprises a purified water supply unit 33 for feeding purified water between the projection lens 27 and wafer 19 mounted on the wafer stage 28, and a purified water recovery unit 34 for recovering the purified water, as shown in FIG. 14. The beam that attempts to pass through the projection lens 27 at a sharp angle is reflected at the boundary surface with the air. Therefore, the resolution does not increase, but when water is added, the beam is bent at the boundary surface of the water, the focus point can be reached, and the focus depth can be improved. In accordance with the immersion exposure method, very detailed machining to a circuit line width of 45 nm is made possible because an equivalent wavelength (λ/n) of 134 nm can be achieved even if an ArF excimer laser having a wavelength of 193 nm is used as a beam source.

The biased-magnification photomask of the present invention can be used because the scan exposure method for moving and exposing the wafer 19 by using the step-and-scan technique is adopted in the exposure apparatus 32. In other words, a high-definition pattern can be formed in the same manner as the scanner 20 described above by scanning and exposing the wafer 19 while moving the biased-magnification photomask at a prescribed velocity in accordance with the magnification bias of the photomask and the scanning velocity of the wafer. In particular, a pattern with a higher resolution can be obtained in comparison with the scanner 20 because the immersion exposure method is adopted.

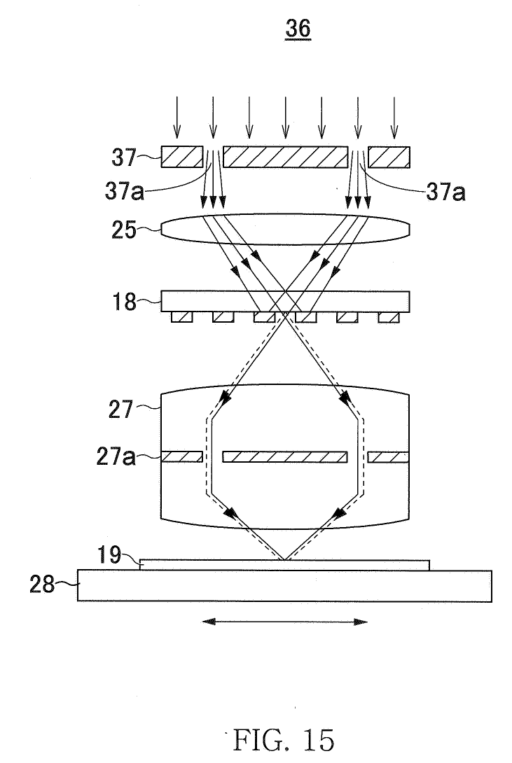

FIG. 15 is a schematic diagram showing a configuration of the exposure apparatus according to yet another embodiment of the present invention.

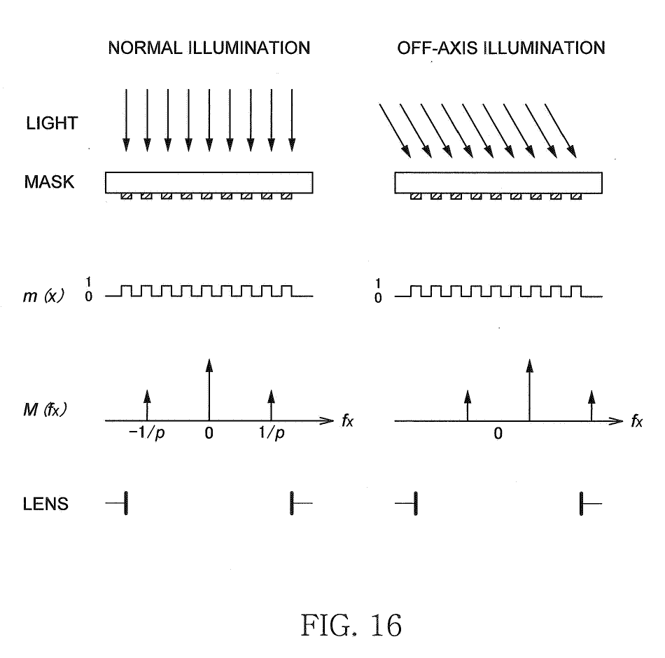

As shown in FIG. 15, a modified illumination (off-axis illumination) method is adopted in the exposure apparatus 36, and the exposure apparatus features an aperture for off-axis illumination 37 for implementing off-axis illumination. The aperture for off-axis illumination is disposed in the Fourier transform plane of the illumination optical system. Beam emitted from the light source passes through the transmission window 37a in the aperture for off-axis illumination 37 and enters the condenser lens 25. In other words, the position of illumination in the case that exposure is carried out using off-axis illumination is offset from the optical axis of the optical system. Thus, with off-axis illumination, 0 order beam and +1 order beam travels while offset from the center of the optical axis of the optical system, as shown in FIG. 16. Therefore, beam that is far from the center of the optical axis (+1 order beam, in this case) is not used, and only the two components proximate to the optical axis (0 and −1 order beam) are used. The DOF focal depth of a compact pattern is thereby increased, and the range of conditions in which drawing can be performed is expanded.

The exposure apparatus 36 which uses the modified illumination method is also capable of adopting a scan exposure technique in which a wafer 19 is moved and exposed using the step-and-scan technique, allowing the biased-magnification photomask of the present invention to be used. In other words, a high-definition pattern can be formed in the same manner as in the scanner 20 described above by scanning and exposing the wafer 19 while moving the biased-magnification photomask at a prescribed velocity in accordance with the magnification bias of the photomask and the scanning velocity of the wafer. In particular, a pattern with a higher resolution can be obtained in comparison with the scanner 20 described above because the modified illumination method is adopted. A pattern with a higher resolution can be obtained if the modified illumination method and the immersion exposure method described above are combined.

Next, a double exposure method using the biased-magnification photomask will be explained. If a high-definition dense hole pattern or a high-definition dense land pattern is formed, the double exposure method is effective.

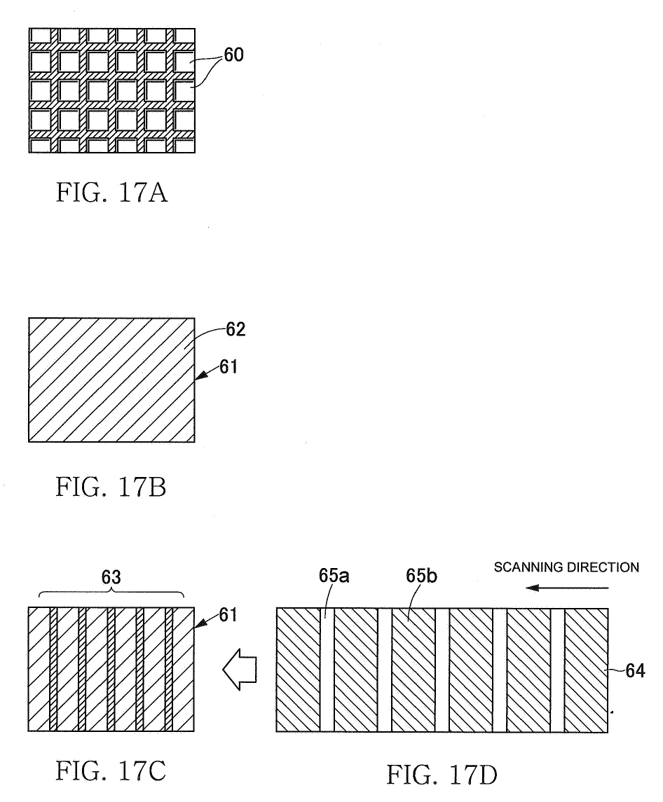

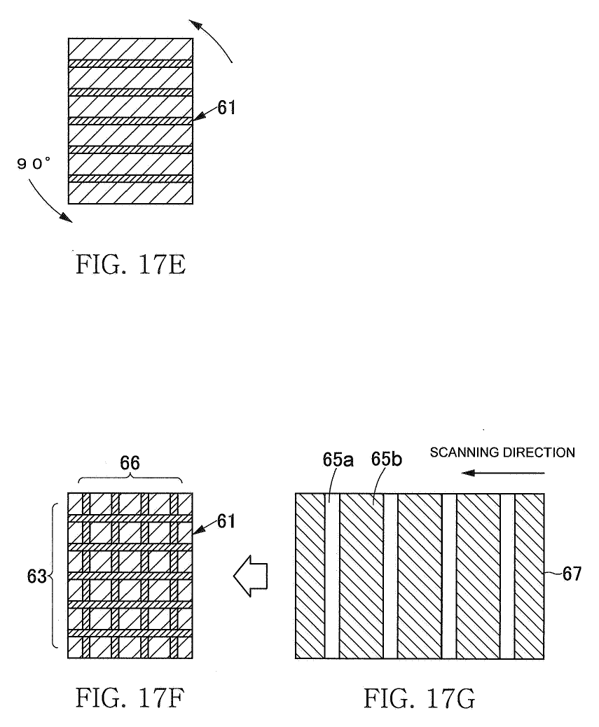

FIGS. 17A through 17F are schematic plan views for explaining the double exposure method.

For example, when forming a dense hole pattern 60 as shown in FIG. 17A in the negative resist process, a wafer 61 on which the photo resist 62 is coated is first prepared (FIG. 17B), and a latent image of first line patterns 63 is formed on the wafer 61 (FIG. 17C) by the double exposure method of the present embodiment. In this case, a biased-magnification photomask 64 containing a mask pattern corresponding to the first line patterns 63 is prepared (FIG. 17D), and scan exposure of the wafer 61 by using the biased-magnification photomask 64 is performed. The mask pattern of the biased-magnification photomask 64 comprises an opening region 65a corresponding to the first line patterns, and a light-blocking region 65b excepting the opening region 65a, and the width of the opening region 65a is elongated in the scanning direction at a prescribed magnification bias. As shown in FIG. 17C, the latent image of the first line patterns 63 is formed on the wafer 61 by scanning and exposing the wafer 61 by using such a biased-magnification photomask 64.

Next, the wafer 61 is rotated at 90 degrees (FIG. 17E), after which a latent image of second line patterns 66 orthogonal to the latent image of the first line patterns 63 is formed on the wafer 61 (FIG. 17F) In this case, a biased-magnification photomask 67 containing a mask pattern corresponding to the second line patterns 66 is prepared (FIG. 17G), and scan exposure of the wafer using the biased-magnification photomask 67 is performed. Therefore, as shown in FIG. 17F, the latent image of the second line patterns 66 is formed on the wafer 61. Furthermore, the wafer 61 is developed and the resist 62 excepting the exposure region is removed. The dense hole pattern 60 is thus obtained as shown in FIG. 17A.

In case of using the ordinary photomask, variation of the process accuracy of the photomask increases as the pattern becomes fine. However, in case of using a biased-magnification photomask, since the dimensional accuracy of the mask can be higher in one direction, it is effective in the double exposure method. The double exposure method is not limited in forming the hole pattern as described above, and may be applied to various patterns.

In the condition in proximity to the resolution limit, the line width and the space width are formed in a proportion of one to one. However, in the above biased-magnification photomask, the line width (width of the opening region) is narrower than the space width (width of the light-blocking region). This is adjusted by the following control method.

FIGS. 18A and 18B are schematic cross-sectional views showing a method of adjusting the width of the mask pattern formed on the photomask.

When expanding the width of the mask pattern, as shown in FIG. 18A, a resist pattern 74 which has a predetermined width in proximity to the resolution limit is formed on the surface of the mask material 73, after which the mask material 73 is patterned by using the resist pattern 74. The mask pattern 73a which has a predetermined line width is therefore formed. Next, a sidewall 73b is formed by forming a thin mask film composed of the same material on the mask pattern 73a and etching back the film. Accordingly, the width of the line pattern can be expanded.

When narrowing the width of the mask pattern, as shown in FIG. 18B, a resist pattern 74 which has a predetermined width in proximity to the resolution limit is formed on the surface of the mask material 73, after which the trimming process with an O₂ plasma treatment is performed. The width of the resist pattern 74 is therefore narrowed. Next, a mask pattern 73c which is narrower than the line width of the initial resist pattern 74 is formed by using the resist pattern 74 and patterning the mask material 73. Accordingly, the width of the line pattern can be narrowed.

The present invention has thus been shown and described with reference to specific embodiments. However, it should be noted that the present invention is in no way limited to the details of the described arrangements but changes and modifications may be made without departing from the scope of the appended claims.

For example, in the embodiments described above, the reduced projection optical system of the scanner 20 is configured with a projection lens 27, as shown in FIG. 12, but the present invention in not limited to such a configuration, and the configuration may also be one in which only mirrors and other reflective optical systems are used.

Also, in the embodiments described above, the mask magnification in the Y direction is set to a magnification that exceeds the mask magnification in the X direction, but the X and Y directions are set for convenience of description, and the mask magnification in the X direction can be set to have a high magnification. In such a case, however, it is apparent that the scan direction must be set in the X direction.

What is claimed is:

1. A photomask that is used in a scanning exposure apparatus, comprising:
a mask pattern elongated in the scanning direction at a prescribed magnification bias.

2. The photomask as claimed in claim 1, wherein the lengthwise direction of the mask pattern is more Q proximate to the direction orthogonal to the scanning direction than to the scanning direction.

3. The photomask as claimed in claim 1, wherein the mask pattern has a repeating pattern that is periodically arrayed with a prescribed pitch.

4. The photomask as claimed in claim 1, wherein the repeating pattern includes any of the following: line and space; dense holes; a dense pillar pattern; a ring pattern; and a U-shaped pattern.

5. The photomask as claimed in claim 1, wherein the magnification bias is set over one times.

6. The photomask as claimed in claim 1, further comprising information about the magnification bias recorded in an outside exposure area.

7. The photomask as claimed in claim 1 including an ordinary binary photomask.

8. The photomask as claimed in claim 1 including an attenuated, alternative, or chromeless phase shift mask.

9. An exposure method in which a wafer is exposed according to a step-and-scan technique that uses a photomask having a mask pattern elongated in the scanning direction at a prescribed magnification bias.

10. The exposure method as claimed in claim 9, comprising:
a photomask movement velocity determination step for determining the movement velocity of the photomask on the basis of the magnification bias and the movement velocity of the wafer; and
a scan exposure step for exposing the photomask by moving the wafer at a prescribed scanning velocity while illuminating the wafer with slitted beam and moving the photomask at the movement velocity of the photomask in synchronism with the wafer.

11. The exposure method as claimed in claim 10, wherein the photomask movement velocity determination step including a step for setting the photomask movement velocity to n times the movement velocity of the wafer, where n (n>1) is the mask magnification in the scanning direction, and m (n>m>1) is the mask magnification in the direction orthogonal to the scanning direction.

12. The exposure method as claimed in claim 10 further comprising a magnification bias information reading step for reading information about the magnification bias recorded on the photomask, prior to the scanning velocity determination step.

13. The exposure method as claimed in claim 10 further comprising a wafer direction adjustment step for adjusting the orientation of the wafer on the basis of information about the magnification bias, prior to the scan exposure step.

14. A method of forming a pattern on a wafer, comprising the steps of:
forming a latent image of a first plurality of line patterns on a wafer by using a first photomask having a mask pattern elongated in the scanning direction at a prescribed magnification bias, and scanning and exposing the wafer;
forming a latent image of a second plurality of line patterns that is orthogonal to the first line patterns on the wafer by using a second photomask having a mask pattern elongated in the scanning direction at the prescribed magnification bias; and
forming a dense hole pattern or a dense land pattern by developing the wafer.

15. The method of forming a pattern on a wafer as claimed in claim 14, further including the step of expanding the width of the dense hole pattern or the dense land pattern that is formed on the wafer.

16. An exposure apparatus for exposing a wafer in accordance with the step-and-scan technique by using a photomask that has a mask pattern elongated in the scanning direction at a prescribed magnification bias, comprising:
an illumination system for illuminating slitted beam on the photomask;
a reduced projection exposure apparatus for reducing and projecting on the wafer the beam that has passed through the photomask; and
scan exposure means for scanning and exposing the wafer at a prescribed scanning velocity in accordance with one of the mask magnifications of the photomask.

17. The exposure apparatus as claimed in claim 16, wherein the scan exposure means comprises a photomask stage on which a photomask is mounted, a wafer stage on which the wafer is mounted, and scan control means for moving the photomask stage and the wafer stage in the reverse direction in synchronism with each other.

18. The exposure apparatus as claimed in claim 17, wherein the scan exposure means sets the movement velocity of the photomask stage to the movement velocity of the wafer stage, where n (n>1) is the mask magnification in the scanning direction, and m (n>m>1) is the mask magnification in the direction orthogonal to the scanning direction.

19. The exposure apparatus as claimed in claim 16 further comprising:
magnification bias information reading means for reading information about the magnification bias recorded on the photomask; and
scanning velocity determination means for determining the movement velocity of the photomask stage on the basis of information about the magnification bias and the movement velocity of the wafer.

20. The exposure apparatus as claimed in claim 19, wherein the wafer stage further comprises wafer rotation means, and the wafer rotation means adjusts the orientation of the wafer on the basis of information about the magnification bias.

21. The exposure apparatus as claimed in claim 16 that exposure the wafer with an immersion exposure method.

22. The exposure apparatus as claimed in claim 16 that exposure the wafer with a modified illumination method.

23. A photomask pattern production method, comprising:
an actual pattern production support step for supporting production of a drawing of an actual pattern having an equivalent longitudinal and transverse ratio projected on a wafer;
an auxiliary pattern generation step for generating an auxiliary pattern on the basis of the actual pattern;
a combined pattern generation step for generating a combined pattern of the actual pattern and the auxiliary pattern; and
a conversion step for converting the dimensions in the longitudinal and transverse directions of the combined pattern using a prescribed mask magnification.

24. The photomask pattern production method as claimed in claim 23, wherein the actual pattern production support step preferably includes a step for displaying the actual pattern and the dimension display scale thereof using an equivalent longitudinal and transverse ratio, and the conversion step preferably includes a step for displaying the combined pattern using an equivalent longitudinal and transverse ratio and displaying the dimensions after the dimension display scale thereof has been enlarged.

25. A pattern formation method that uses the photomask having a mask pattern elongated in the scanning direction at a prescribed magnification bias, comprising the steps of:
forming a first wiring pattern on a wafer; and
rotating the wafer while the photomask scanning direction is kept the same direction and forming a second wiring pattern that is substantially orthogonal to the first wiring pattern on the wafer.

26. A pattern formation method, comprising:
an ordinary pattern formation step for forming a pattern using a photomask in which the mask magnification is equal in the longitudinal and transverse directions; and
a high-resolution pattern formation step for forming a pattern using a photomask in which the mask magnifications are different in the longitudinal and transverse directions.

27. A pattern formation method in which scanning and exposing is carried out in the direction orthogonal to the lengthwise direction of a repeating pattern when a hole pattern is formed in accordance with the repeating pattern on a wafer that has the pattern.

28. A semiconductor device manufactured using the photomask having a mask pattern elongated in the scanning direction at a prescribed magnification bias.

29. A semiconductor device manufactured using the exposure method in which a wafer is exposed according to a step-and-scan technique that uses a photomask having a mask pattern elongated in the scanning direction at a prescribed magnification bias.

30. A semiconductor device manufactured using the method of forming a pattern on a wafer, wherein the method of forming the pattern comprises the steps of:
forming a latent image of a first plurality of line patterns on a wafer by using a first photomask having a mask pattern elongated in the scanning direction at a prescribed magnification bias, and scanning and exposing the wafer;
forming a latent image of a second plurality of line patterns that is orthogonal to the first line patterns on the wafer by using a second photomask having a mask pattern elongated in the scanning direction at the prescribed magnification bias; and
forming a dense hole pattern or a dense land pattern by developing the wafer.

31. A semiconductor device manufactured using the pattern formation method, wherein the pattern formation method that uses the photomask having a mask pattern elongated in the scanning direction at a prescribed magnification bias, comprising the steps of:
forming a first wiring pattern on a wafer; and
rotating the wafer while the photomask scanning direction is kept the same direction and forming a second wiring pattern that is substantially orthogonal to the first wiring pattern on the wafer.
